(19) United States
(12) Patent Application Publication
(10) Pub. No.: US 2013/0288482 A1
(43) Pub. Date: Oct. 31, 2013

(54) METHODS OF FORMING A PATTERN

(71) Applicant: SAMSUNG ELECTRONICS CO., LTD., Gyeonggi-do (KR)

(72) Inventors: Jae-Woo Nam, Seoul (KR); Kyoung-Seon Kim, Gyeonggi-do (KR); Eun-Sung Kim, Seoul (KR); Chul-Ho Shin, Gyeonggi-do (KR); Shi-Yong Yi, Gyeonggi-do (KR)

(73) Assignee: SAMSUNG ELECTRONICS CO., LTD., Gyeonggi-do (KR)

(21) Appl. No.: 13/630,270

(22) Filed: Sep. 28, 2012

(30) Foreign Application Priority Data
Apr. 26, 2012 (KR) 10-2012-0043595

(51) Int. Cl. H01L 21/31

(52) U.S. Cl. 438/703; 438/694; 438/778; 257/E21.24

(57) ABSTRACT

In a method of forming a pattern, a photoresist pattern is formed on a substrate including an etching target layer. A surface treatment is performed on the photoresist pattern to form a guide pattern having a higher heat-resistance than the photoresist pattern. A material layer including a block copolymer including at least two polymer blocks is coated on a portion of the substrate exposed by the guide pattern. A micro-phase separation is performed on the material layer to form a minute pattern layer including different polymer blocks arranged alternately. At least one polymer block is removed from the minute pattern layer to form a minute pattern mask. The etching target layer is etched by using the minute pattern mask to form a pattern. Minute patterns may be formed utilizing a less complex process that those employed during conventional processes of forming a minute pattern.

### CROSS-REFERENCE TO RELATED APPLICATION

This application claims priority under 35 USC §119 to Korean Patent Application No. 10-2012-0043595 filed on Apr. 26, 2012 in the Korean Intellectual Property Office (KIPO), the entire disclosure of which is incorporated herein by reference.

### BACKGROUND

Example embodiments relate to methods of manufacturing a semiconductor device. More particularly, example embodiments relate to methods of forming a pattern that may be used in semiconductor devices.

As semiconductor devices are becoming more highly integrated, patterns having finer line widths are desired. In order to decrease the line width of a photoresist pattern through an exposure process, research has been conducted on methods of decreasing the wavelength of a light source that is applied during the exposure process, methods of increasing the effective aperture of a lens, etc.

### SUMMARY

Example embodiments provide a method of forming a minute pattern by overcoming limitations of the exposure process.

According to example embodiments, there is provided a method of forming a pattern. In the method, a photoresist pattern is formed on a substrate including an etching target layer. Then, a surface treatment is conducted with respect to the photoresist pattern to form a guide pattern having greater heat-resistance than the photoresist pattern, and a material layer including a block copolymer including at least two polymer blocks is coated on a portion of the substrate exposed by the guide pattern. Thereafter, a micro-phase separation is performed on the material layer to form a minute pattern layer including different polymer blocks arranged alternately, and at least one polymer block is removed from the minute pattern layer to form a minute pattern mask. The etching target layer is etched by using the minute pattern mask to form the pattern.

In example embodiments, the surface treatment may include at least one of a plasma treatment, an ozone vapor phase treatment, an ion doping process and a UV light exposing process.

In example embodiments, the surface treatment may include plasma treatment, and the surface treatment may be performed by using may include source gas, example of the source gas may include Ar, N₂, HBr, O₂, etc. These can be used alone or in a mixture thereof.

In example embodiments, the surface treatment may include the plasma treatment, and the surface treatment may be performed at a temperature in a range of about 10° C. to about 100° C. for a time period in a range of about 30 seconds to about 300 seconds.

In example embodiments, the photoresist pattern may include one of a positive type photoresist pattern and a negative type photoresist pattern.

In example embodiments, exemplary photoresist patterns may be formed by using a photoresist for an i-line, a photoresist for a KrF laser, a photoresist for ArF drying, a photoresist for ArF immersion, a photoresist for extreme ultraviolet (EUV) light, etc. These photoresists can be used alone or in a combination thereof.

In example embodiments, the photoresist pattern may be formed by coating a photoresist on the substrate. Then, the photoresist may be patterned by using a photolithography process.

In example embodiments, the guide pattern may have a first glass transition temperature that is higher than a second glass transition temperature of the material layer.

In example embodiments, the micro-phase separation may be performed by annealing at a temperature ranging from a second glass transition temperature of the material layer to a first glass transition temperature of the guide pattern.

In example embodiments, forming an interface layer for covering the etching target layer may be further included. The interface layer may be formed between the photoresist pattern and the etching target layer.

According to example embodiments, a guide pattern formed by surface treating a photoresist pattern may be formed on a substrate. At an opening portion between the guide patterns, a directed self assembly structure of a block copolymer may be formed to form a pattern having a minute width that may overcome the limits of resolution in a photolithography process. The guide pattern may be formed without applying a separate thin film forming process or an etching process. The minute pattern may thus be formed through a more simplified process.

### BRIEF DESCRIPTION OF THE DRAWINGS

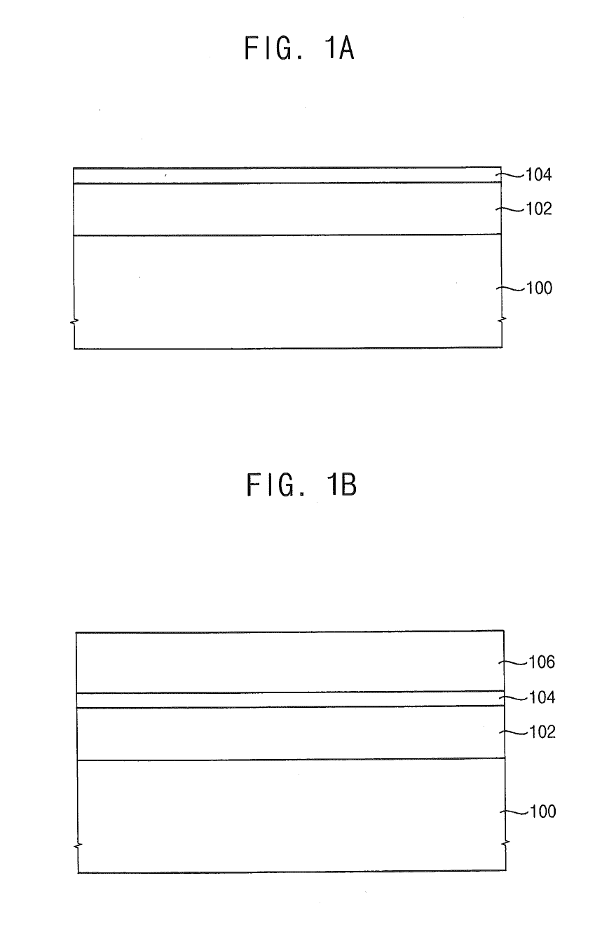

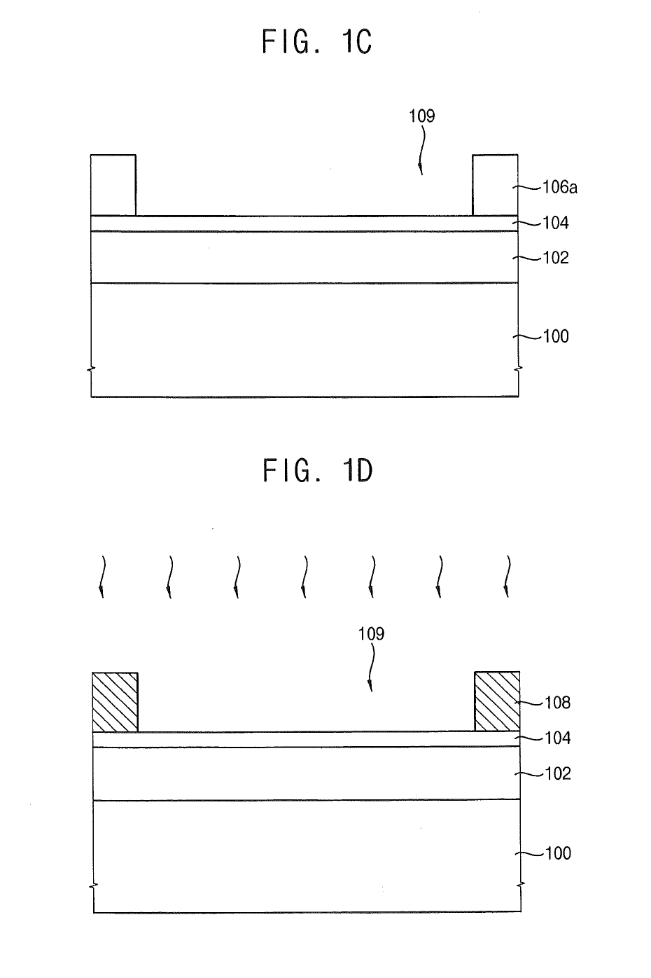

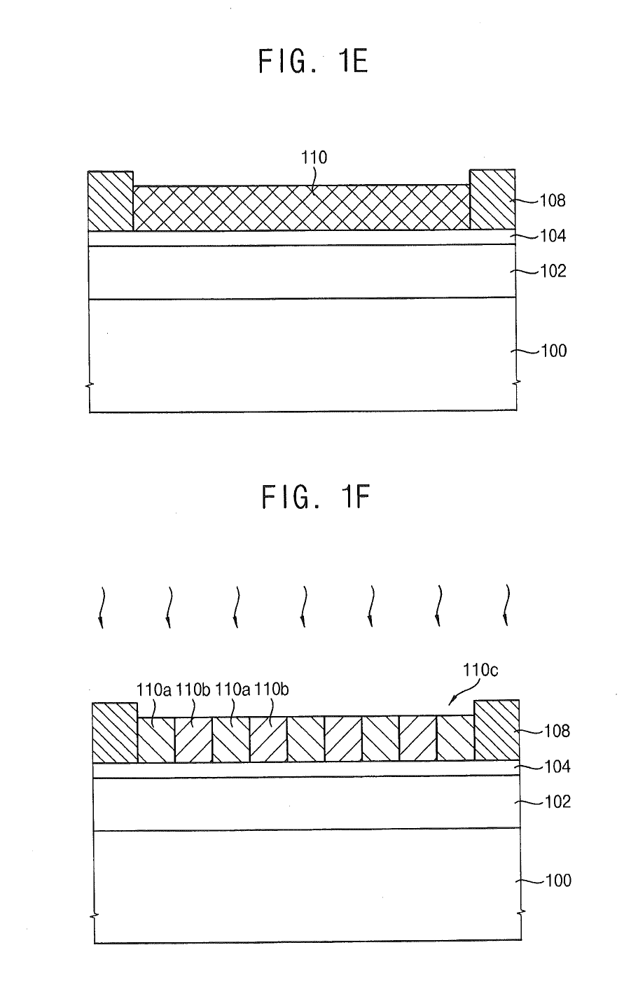

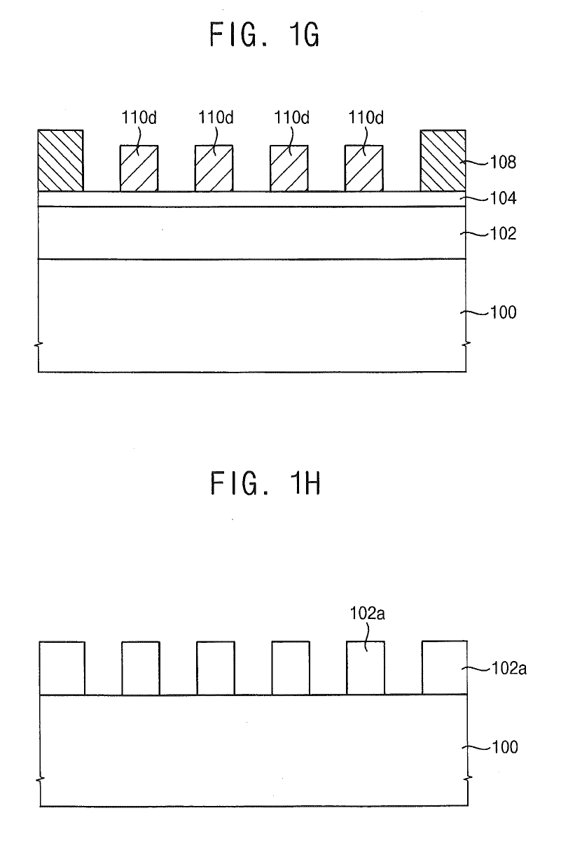

Example embodiments will be more clearly understood from the following detailed description taken in conjunction with the accompanying drawings. FIGS. 1A to 1H represent non-limiting, example embodiments as described herein.

In particular, FIGS. 1A to 1H are cross-sectional views illustrating a method of forming a pattern in accordance with example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In example embodiments, a pattern density may be increased by controlling a pattern pitch using a material showing self assembly behavior to accomplish a pattern having a minute pattern width. Particularly, repeatedly arranged minute structures may be obtained through the spontaneous self assembly by using the phenomenon of phase separation of a block copolymer. According to the process of forming a pattern using the self-assembly properties of the block copolymer, unlike in a common photolithography process, the size of the obtained minute patterns may be similar to a thickness of a mono-molecular layer. Thus, minute patterns that can exceed the limits of resolution in a common photolithography process may be formed.

The block copolymer is a functional polymer obtained by combining polymer blocks having two or more different structures into one polymer through covalent bonding. Each of the polymer blocks constituting the block copolymer may demonstrate a different mixing property and/or a selective solubility due to at least a different chemical structure of each block. The block copolymer may form a self-assembled structure through micro-phase separation or a selective dissolution in a liquid phase or a solid phase. The forming of a specific shape through the self assembly of the block copolymer may be affected by physical and/or chemical properties of the block polymer. Particularly, when a di-block copolymer formed by using two different polymers is self assembled on a bulk substrate, the volume fraction of each polymer block constituting the block copolymer may be primarily affected by the molecular weight of each polymer block. The self-assembled structure of the block copolymer may be determined as one of various structures such as a three-dimensional structure including a cubic structure and a double gyroidal structure, and a two-dimensional structure including a hexagonal packed column structure and a lamellar structure, according to the volume fraction, the temperature, the molecule size, etc, of each of the polymer blocks constituting the block copolymer. In this case, the size of each of the polymer blocks in each structure may be proportional to the molecular weight of the corresponding polymer block.

The self-assembled block copolymers having the two-dimensional structure such as the hexagonal column structure or the lamellar structure may be used for forming the minute pattern of a semiconductor device. In order to apply the block copolymer having the hexagonal structure, the structure may be obtained by hexagonally filling cylindrical columns. Therefore, the orientation of the thus obtained structure may be relatively simple. According to the orientation direction of the columns, line and space patterns may be formed, or a plurality of repeatedly arranged hole patterns may be formed. The lamellar structure may be obtained by repeatedly stacking two-dimensional plate-type structures. When the block copolymer having the lamellar structure is oriented in a vertical direction with respect to the surface of the substrate, line and space patterns having a large aspect ratio may be formed.

The self-assembled structure of the block copolymer may be formed as a minute self-assembled structure that is several nm to several tens of nm, which is proportional to the size of a polymer molecule. Expensive equipment required for performing a process such as a common photolithography process may not be necessary in a process using the self-assembled structure of the block copolymer. Rather, the number of processes may be decreased by using a spontaneous thermodynamic process so that the pattern forming process may be simplified. Through forming the minute patterns by using the self-assembling property of the block copolymer, extremely minute patterns having a size of several nm to several tens of nm, which may be difficult to accomplish by common processing techniques, may be formed. Therefore, diverse applications of the block copolymer in the field of future electronic devices may be possible.

In order to utilize the self-assembling property of the block copolymer for forming a minute pattern necessary for the manufacture of a semiconductor device, a material layer including the block copolymer may be formed as a thin film on a planar layer on a substrate. Then, the block copolymer may be heated to a temperature higher than the glass transition temperature of the copolymer to induce the self-assembling. In this process, the most important factor may be the controlling of the orientation of the minute structure obtained from the self-assembling of the block copolymer. The phenomenon of polymer self-assembly is a spontaneous process brought about by the tendency of molecules to exist in a thermodynamically stable state, and the obtained self-assembled structure may be oriented according to a pre-established design. In order to accomplish the desired orientation, forming the guide patterns on the substrate may be required to induce the orientations of the polymer blocks during the self-assembling.

Hereinafter, example embodiments for forming minute patterns through forming the self-assembled structure will be described in detail with reference to the accompanying drawings. However, the example embodiments of the present inventive concept as described below may be modified in various other forms, and the scope of the present inventive concept below shall not be interpreted as being limited by the example embodiments described above. The example embodiments of the present inventive concept are provided to more completely convey the present inventive concept to those having ordinary skill in the art. In the drawings, various elements and regions are roughly represented. Therefore, the present inventive concept is not to be limited by the relative sizes and distances depicted in the attached drawings.

FIGS. 1A to 1H are cross-sectional views illustrating a method of forming a pattern in accordance with example embodiments.

Referring to FIG. 1A, an interface layer 104 may be formed on an etching target layer 102 on a substrate 100. The etching target layer 102 may be formed as an insulating layer or a conductive layer. Particularly, the etching target layer 102 may be formed as an insulating layer such as an oxide layer, a nitride layer, an oxynitride layer, etc. or a metal layer such as aluminum, tungsten, Au, Pt, or Cu. When the substrate 100 is etched, the formation of the etching target layer 102 may be omitted.

The interface layer 104 may be provided to improve the function of vertically arranging the block copolymer or to prevent reflections during exposing process. The interface layer 104 may cover the etching target layer 102. The interface layer 104 may be formed, e.g., as an organic antireflective layer or by using neutral polymers. The neutral polymers may have neutral property with respect to polymer blocks comprising a block copolymer used for sequent processing of forming a material layer including the block copolymer.

Any organic antireflective layer used in a common photolithography process may be used as the interface layer 104. Particularly, the interface layer 104 may be an organic anti-reflective coating (ARC) for a KrF excimer laser, an ArF excimer laser, or other type of light source. The interface layer 104 may be formed by using an ARC material used in an immersion lithography process. Examples of the organic ARC material may include the “NCA” series and “NCST” series (commercial name purchasable from Nissan Chemical Industries, Ltd.), the “XP” series (commercial name purchasable from Rohm and Haas Electronic Materials, RHEM), the “SNSA” series (commercial name purchasable from ShinEtsu Chemical Co), etc. These can be used alone or in a mixture thereof.

In order to form the interface layer 104, the organic ARC material may be coated on the etching target layer 102 and then heat treated to cross-link the organic ARC material.

Referring to FIG. 1B, a photoresist layer 106 may be coated on the interface layer 104. The photoresist layer 106 may be formed by using a photoresist used in a common photolithography process.

Any one of the photoresist for an i-line, photoresist for a KrF, photoresist for ArF drying, photoresist for ArF immersion, and photoresist for extreme ultraviolet (EUV) light may be used irrespective of the light source applied in a photolithography process. The photoresist layer 106 may be formed by using a positive-type photoresist or a negative-type photoresist.

Referring to FIG. 1C, an exposure process and a developing process may be performed on the photoresist layer 106 by using a specific pattern to form a photoresist pattern 106a to expose a portion of the interface layer 102.

The exposure and developing process may be conducted with an optimized method for the photoresist material formed on the substrate 100.

The photoresist pattern 106a may be provided as a preliminary guide pattern for inducing the orientation of the polymer blocks during the self assembling. Thus, the shape of the photoresist pattern 106a may be changed according to the shape of a desirable and finally obtainable pattern.

A planar shape of an opening 109 of the photoresist pattern 106a may be a straight line, a curved line or a linear line having at least one knuckle point. The planar shape of the opening 109 of the photoresist pattern 106a may be a circular line or an ellipsoidal line with a specific position on the substrate 100 as the center.

The photoresist pattern 106a may have a width obtainable within the resolution limits of a common photolithography process. In order to decrease the width of the opening 109 of the photoresist pattern 106a, a thermal flow or a chemical attachment (CAP) process may be conducted after forming the photoresist pattern 106a.

Referring to FIG. 1D, the photoresist pattern 106a may be surface treated to form a guide pattern 108. The guide pattern 108 may be provided through the surface treatment as a deformed photoresist pattern so as to have higher strength, higher hydrophilicity, higher heat-resistance, and lower solubility with respect to a solvent for dissolving the block copolymer.

The surface treatment may include a plasma treatment process. The plasma treatment may be performed at a temperature lower than a first glass transition temperature of the photoresist material. The plasma treatment process may be conducted at a temperature ranging from about 10 to about 100 degrees Celsius. Particularly, the plasma treatment process may be conducted at room temperature, for example, in a range of about 20 to about 25 degrees Celsius.

When the plasma treatment is conducted within 30 seconds or less, it may be difficult to obtain a guide pattern having desired properties. When the plasma treatment is conducted over 300 seconds, a plasma attack on the photoresist material may occur. The plasma treating process may be conducted for a period of time in a range of about 30 to about 300 seconds. However, in some embodiments, the plasma treatment may not be needed over 100 seconds because the desired properties of the guide pattern may be obtained within a time period ranging from about 30 to about 100 seconds.

Particularly, the plasma treatment may be performed on the substrate 100 including the photoresist pattern 106a by using a source gas. Example of the source gas may include Ar, N₂, HBr, O₂, etc. These source gases can be used alone or in a mixture thereof. Plasma treatment using ozone may not be desirable because, in instances, the photoresist pattern may not be maintained at above 200 degrees Celsius if the photoresist pattern is plasma treated using ozone.

The guide pattern 108 may have a decreased contact angle when compared to the photoresist pattern 106a prior to the plasma treatment. The guide pattern 108 may have a higher hydrophilicity than the photoresist pattern 106a that is not treated with plasma. In addition, the guide pattern 108 may have increased heat-resistance when compared to the photoresist pattern 106a that is not treated with plasma. Generally, the pattern shape does not change significantly, and the width of an opening portion between the patterns does not change significantly, even when the guide pattern 108 is heat treated at a high temperature over 200 degrees Celsius. In addition, the guide pattern 108 may have increased strength over the photoresist pattern 106a that is not treated with plasma so that the pattern is not damaged but may be maintained during the performance of a subsequent spin coating process for forming a block copolymer material layer. Further, since the guide pattern 108 hardly dissolves in a solvent for dissolving the subsequently applied block copolymer, the guide pattern 108 is not damaged and may be maintained.

As another example, the surface treatment process may include an ozone vapor phase process, an ion doping process, a UV exposing process, etc.

That is, at least one process from among the ozone vapor phase process, the ion doping process and the UV exposing process may be conducted as the surface treatment process instead of the plasma treatment process. Alternately, the plasma treatment process may be conducted as the surface treatment process and then, one of the ozone vapor phase process, the ion doping process and the UV exposing process may be further conducted.

Meanwhile, the photoresist material in the surface un-treated photoresist pattern 106a may reflow, and the shape of the photoresist pattern 106a may be deformed by heat treatment at a high temperature over 180 degrees Celsius. Therefore, the shape of the surface un-treated photoresist pattern 106a may be deformed while conducting a subsequent phase separating process. In addition, since the adhesiveness and the strength of the surface un-treated photoresist pattern 106a may be weak, pattern damage may be generated while conducting a subsequent spin coating for forming a material layer including the block copolymer. Further, since the resistance of the surface un-treated photoresist pattern 106a to a solvent for dissolving a subsequently applied block copolymer is weak, the photoresist pattern 106a may be more readily removed by the solvent. The surface un-treated photoresist pattern 106a may not have any specific hydrophilic or hydrophobic properties.

For at least the above-described reasons, the surface un-treated photoresist pattern 106a may not be used as the guide pattern.

However, the surface treated photoresist pattern in accordance with exemplary embodiments may have higher strength, higher hydrophilicity, higher heat resistance and lower solubility with respect to a solvent, which may be appropriate for the guide pattern.

In accordance with exemplary embodiments, the guide pattern 108 may be formed by using only a photolithography process and a surface treatment process, without separately conducting a thin film forming process and an etching process through photolithography. Accordingly, the generation of a defect accompanying an etching process may be suppressed, and the process may be simplified.

Referring to FIG. 1E, a material layer 110 including the block copolymer may be formed on an exposed portion of the interface layer 104 in the opening 109.

In order to form the material layer 110, the block copolymer may be dissolved in a solvent and then spin coated. The solvent may be toluene, for example. Most of the solvent may be evaporated after the coating. After the spin coating process is performed, the material layer 110 may be formed in the opening 109 between the guide patterns 108. Accordingly, the shape of the material layer 110 may be changed according to the shape of the guide pattern 108.

The material layer 110 may include a block copolymer obtained by using at least two polymer blocks. Particularly, the block copolymer in the material layer 110 may be a block copolymer obtained through a covalent bonding of a first polymer block and a second polymer block in a volume fraction of about 1:1. The block copolymer may be a two-component or di-block copolymer (AB) including two kinds of block copolymers (A and B), a three-component or tri-block copolymer (ABA) including two kinds of block copolymers (A and B), a three-component copolymer (ABC) including three kinds of block copolymers (A, B and C) or a multi-component block copolymer. The block copolymer may include a linear or a branch type polymer having a molecular weight of about 3,000 to about 2,000,000 g/mol.

The block copolymer may include polystyrene-block-polymethylmethacrylate, polybutadiene-block-polybutylmethacrylate, polybutadiene-block-polydimethylsiloxane, polybutadiene-block-polymethylmethacrylate, polybutadiene-block-polyvinylpyridine, polybutylacrylate-block-polymethylmethacrylate, polybutylacrylate-block-polyvinylpyridine, polyisoprene-block-polyvinylpyridine, polyisoprene-block-polymethylmethacrylate, polyhexylacrylate-block-polyvinylpyridine, polyisobutylene-block-polybutylmethacrylate, polyisobutylene-block-polymethylmethacrylate, polyisobutylene-block-polybutylmethacrylate, polyisobtylene-block-polydimethylsiloxane, polybutylmethacrylate-block-polybutylacrylate, polyethylethylene-block-polymethylmethacrylate, polystyrene-block-polybutylmethacrylate, polystyrene-block-polybutadiene, polystyrene-block-polyisoprene, polystyrene-block-polydimethylsiloxane, polystyrene-block-polyvinylpyridine, polyethylethylene-block-polyvinylpyridine, polyethylene-block-polyvinylpyridine, polyvinylpyridine-block-polymethylmethacrylate, polyethyleneoxide-block-polyisoprene, polyethyleneoxide-block-polybutadiene, polyethyleneoxide-block-polystyrene, polyethyleneoxide-block-polymethylmethacrylate, polyethyleneoxide-block-polydimethylsiloxane, polystyrene-block-polyethyleneoxide, polystyrene-block-polymethylmethacrylate-block-polystyrene, polybutadiene-block-polybutylmethacrylate-block-polybutadiene, polybutadiene-block-polydimethylsiloxane-block-polybutadiene, polybutadiene-block-polymethylmethacrylate-block-polybutadiene, polybutadiene-block-polyvinylpyridine-block-polybutadiene, polybutylacrylate-block-polymethylmethacrylate-block-polybutylacrylate, polybutylacrylate-block-polyvinylpyridine-block-polybutylacrylate, polyisoprene-block-polyvinylpyridine-block-polyisoprene, polyisoprene-block-polymethylmethacrylate-block-polyisoprene, polyhexylacrylate-block-polyvinylpyridine-block-polyhexylacrylate, polyisobutylene-block-polybutylmethacrylate-block-polyisobutylene, polyisobutylene-block-polymethylmethacrylate-block-polyisobutylene, polyisobutylene-block-polybutylmethacrylate-block-polyisobutylene, polyisobutylene-block-polydimethylsiloxane-block-polyisobutylene, polybutylmethacrylate-block-polybutylacrylate-block-polybutylmethacrylate, polyethylethylene-block-polymethylmethacrylate-block-polyethylethylene, polystyrene-block-polybutylmethacrylate-block-polystyrene, polystyrene-block-polybutadiene-block-polystyrene, polystyrene-block-polyisoprene-block-polystyrene, polystyrene-block-polydimethylsiloxane-block-polystyrene, polystyrene-block-polyvinylpyridine-block-polystyrene, polyethylethylene-block-polyvinylpyridine-block-polyethylethylene, polyethylene-block-polyvinylpyridine-block-polyethylene, polyvinylpyridine-block-polymethylmethacrylate-block-polyvinylpyridine, polyethyleneoxide-block-polyisoprene-block-polyethyleneoxide, polyethyleneoxide-block-polybutadiene-block-polyethyleneoxide, polyethyleneoxide-block-polystyrene-block-polyethyleneoxide, polyethyleneoxide-block-polymethylmethacrylate-block-polyethyleneoxide, polyethyleneoxide-block-polydimethylsiloxane-block-polyethyleneoxide, polystyrene-block-polyethyleneoxide-block-polystyrene, etc.

The material layer 110 may include a block copolymer obtained by a covalent bond of a first polymer block and a second polymer block in a volume fraction of about 1:1, a first homopolymer having the same repeating unit as the first polymer block and a second homopolymer having the same repeating unit as the second polymer block. For example, when the block copolymer in the material layer 110 is polystyrene (PS)-polymethylmethacrylate (PMMA) copolymer, the material layer 110 may further include PS as the first homopolymer and PMMA as the second homopolymer, respectively. The amount added of the first homopolymer and the second homopolymer in the material layer 110 may be the same. The amount of the first homopolymer and the second homopolymer may be, respectively, about 0 to about 60% by weight based on the amount of the block copolymer.

Referring to FIG. 1F, the components in the material layer 110 may be rearranged through a phase separation of the material layer 110 to form a minute pattern layer 110c including a plurality of first blocks 110a and a plurality of second blocks 110b, which include monomer units having components different from each other. Since the material layer 110 is formed only on the interface layer 104, the minute pattern layer 110c may be formed only on the interface layer 104.

The plurality of the first blocks 110a and the plurality of the second blocks 110b may have different polarities according to the repeating unit of the polymers constituting the first and second blocks 110a and 110b.

The guide pattern 108 may have a high affinity to at least one polymer block from among the polymer blocks 110a and 110b. That is, the guide pattern 108 may be hydrophilic or hydrophobic. When the guide pattern 108 has a lower affinity for a specific polymer block, the phase separation property may be deteriorated so that defects may be generated in the minute pattern. Since the guide pattern 108 may be hydrophilic in exemplary embodiments, the minute pattern may be formed without defects.

Each of the polymer blocks of the block copolymer phase separated from the material layer 110 may have different polarities depending on hydrophilic groups included in the polymer blocks.

As a sidewall of the guide pattern 108, the first block having the hydrophilic property may be addressed. Next to the addressed first block 110a, the second block 110b and the first block 110a may be alternately and repeatedly arranged in that sequence on the interface layer 104.

In order to rearrange the components in the material layer 110 through the phase separation of the material layer 110, the material layer 110 may be annealed at a temperature higher than a second glass transition temperature of the block copolymer (Tg_BC) in the material layer 110. Particularly, in order to perform the phase separation of the material layer 110, the material layer 110 may be annealed at a temperature in a range of about 100° C. to about 190° C. for a period of time in a range of about 1 to about 24 hours. In this case, annealing of the material layer 110 may be performed at a temperature lower than the first glass transition temperature of the guide pattern 108 (Tg_PR).

Since thermal deformation of the guide pattern 108 is not usually generated at a temperature of 200° C. and above, the structure of the guide pattern 108 is not changed significantly but may be maintained at a temperature range for performing the phase separation of the material layer 110.

With the provision of the guide pattern 108, the minute pattern layer 110c formed by the micro-phase separation may include uniformly arranged nano structures of each block.

Referring to FIG. 1G, one of the plurality of the first blocks 110a or the plurality of the second blocks 110b may be removed from the minute pattern layer 110c to form a minute pattern mask 110d. The plurality of the first blocks 110a may be removed as illustrated in FIG. 1G. However, the present inventive concept shall not be limited to this exemplary embodiment. The plurality of the second blocks 110b may be removed to form the minute pattern mask. In this case, the same effect may be obtained as described in the present inventive concept.

In order to remove one of the plurality of the first blocks 110a or the plurality of the second blocks 110b, the plurality of the blocks to be removed may be exposed to UV light or exposed to oxygen plasma for photodecomposition, after which the photo decomposed portion may be stripped off using a cleaning solution.

Referring to FIG. 1H, the exposed portion of the interface layer 104 may be etched by using the minute pattern mask 104 as an etching mask. Then, the etching target layer 102 may be etched to obtain a desired minute pattern 102a.

When the forming step of the etching target layer 102 is omitted, the substrate 100 may be etched by using the minute pattern mask 110d as an etching mask to obtain the desired minute pattern 102a.

Then, the minute pattern mask 110d may be removed, and unnecessary layers remaining on the upper portion of the minute pattern 102a may be removed.

### Experimental Embodiment

Experiments were conducted to confirm changes in polarity of the surface of the photoresist layer when treated with plasma.

### Sample 1

A photoresist layer was formed by spin coating a negative-type photoresist layer on a substrate. Then, plasma treatment was performed on the photoresist layer using an HBr source at room temperature for 1 minute.

### Sample 2

A photoresist layer was formed by spin coating a negative-type photoresist layer on a substrate. Then, plasma treatment was performed on the photoresist layer using an Ar source at room temperature for 1 minute.

### Sample 3

A photoresist layer was formed by spin coating a negative-type photoresist layer on a substrate. Then, plasma treatment was performed on the photoresist layer using an N₂ source at room temperature for 1 minute.

### Comparative Sample

A photoresist layer was formed by spin coating a negative-type photoresist layer on a substrate. Then, plasma treatment was not performed.

In order to confirm the change in polarity of the surface portion with respect to each sample, the contact angle was measured.

TABLE 1

| | | | |
|---|---|---|---|
| | | | Comparative |
| Sample 1 | Sample 2 | Sample 3 | Sample |

| | | | | |
|---|---|---|---|---|
| Contact angle (°) | 56.5 | 50.4 | 43.9 | 86.8 |

Referring to Table 1, the contact angle of the photoresist layer was found to be less when plasma treatment was not performed. Through the plasma treatment, the polarity of the photoresist layer was confirmed to have changed so as to have a hydrophilic property. Thus, the plasma treated photoresist pattern may be appropriately used as the guide pattern.

The present inventive concept may be widely applied to manufacturing processes for semiconductor devices that include extremely minute patterns.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a pattern, comprising:
forming a photoresist pattern on a substrate including an etching target layer;
performing a surface treatment on the photoresist pattern to form a guide pattern having a greater heat-resistance than the heat-resistance of the photoresist pattern;
applying a material layer including a block copolymer including at least two polymer blocks on at least a portion of the substrate exposed by the guide pattern;
performing a micro-phase separation on the material layer to form a minute pattern layer including different polymer blocks arranged alternately;
removing at least one polymer block from the minute pattern layer to form a minute pattern mask; and
etching the etching target layer by using the minute pattern mask to form the pattern.

2. The method of claim 1, wherein the surface treatment includes at least one of a plasma treatment, an ozone vapor phase treatment, an ion doping process and an ultraviolet (UV) light exposing process.

3. The method of claim 1, wherein the surface treatment includes a plasma treatment, and the surface treatment is performed by using at least one source gas selected from the group consisting of Ar, N₂, HBr and O₂.

4. The method of claim 3, wherein the surface treatment includes the plasma treatment, and the surface treatment is performed at a temperature in a range of about 10° C. to about 100° C. for a period of time in a range of about 30 seconds to about 300 seconds.

5. The method of claim 1, wherein the photoresist pattern includes one of a positive-type photoresist pattern and a negative-type photoresist pattern.

6. The method of claim 1, wherein the photoresist pattern is formed by using at least one photoresist selected from the group consisting of a photoresist for an i-line, a photoresist for a KrF excimer laser, a photoresist for ArF drying, a photoresist for ArF immersion and a photoresist for extreme ultraviolet (EUV) light.

7. The method of claim 1, wherein forming the photoresist pattern comprises:
applying a photoresist to the substrate; and
patterning the photoresist by using a photolithography process.

8. The method of claim 1, wherein the guide pattern has a first glass transition temperature that is higher than a second glass transition temperature of the material layer.

9. The method of claim 1, wherein the micro-phase separation is performed by annealing at a temperature ranging from a second glass transition temperature of the material layer to a first glass transition temperature of the guide pattern.

10. The method of claim 1, further comprising:
forming an interface layer for covering the etching target layer, the interface layer being formed between the photoresist pattern and the etching target layer.

11. A method of forming, a pattern, comprising:
forming a photoresist pattern on a substrate including an etching target layer;
subjecting the photoresist pattern to a surface plasma treatment to form a guide pattern having a greater heat-resistance than the heat-resistance of the photoresist pattern;
applying a material layer including a block copolymer including at least two polymer blocks on at least a portion of the substrate exposed by the guide pattern;
performing a micro-phase separation on the material layer to form a minute pattern layer including different polymer blocks arranged alternately;
removing at least one polymer block from the minute pattern layer to form a minute pattern mask; and
etching the etching target layer by using the minute pattern mask to form the pattern.

12. The method of claim 11, wherein the photoresist pattern is subjected to at least one of an ozone vapor phase treatment, an ion doping process and an ultraviolet (UV) light exposing process after being subjected to the surface plasma treatment.

13. The method of claim 11, wherein the plasma treatment is conducted for a period of time in a range of about 30 seconds to about 100 seconds.

14. A method of forming a guide pattern for self-assembled materials for semiconductor devices, the method comprising:
forming a photoresist pattern on a substrate including an etching target layer;
performing a surface treatment on the photoresist pattern to form a guide pattern having a greater heat-resistance than the heat-resistance of the photoresist pattern, wherein the surface treatment includes at least one of a plasma treatment, an ozone vapor phase treatment, an ion doping process and an ultraviolet (UV) light exposing process, and the surface treatment is performed by using at least one source gas selected from the group consisting of Ar, N₂, HBr and O₂.

15. The method of claim 14, wherein the guide pattern is hydrophilic.

16. The method of claim 14, wherein the guide pattern is hydrophobic.

17. The method of claim 14, wherein forming the photoresist pattern comprises:
applying a photoresist to the substrate; and
patterning the photoresist by using a photolithography process.

18. The method of claim 14, wherein the photoresist pattern is formed by using at least one photoresist selected from the group consisting of a photoresist for an i-line, a photoresist for a KrF excimer laser, a photoresist for ArF drying, a photoresist for ArF immersion and a photoresist for extreme ultraviolet (EUV) light.

19. The method of claim 14, wherein the surface treatment is performed at a temperature in a range of about 10° C. to about 100° C. for a period of time in a range of about 30 seconds to about 300 seconds.

20. The method of claim 14, wherein the surface treatment is performed at a room temperature for a period of time in a range of about 30 seconds to about 100 seconds.
